(19) United States
(12) Patent Application Publication
(10) Pub. No.: US 2022/0140061 A1
(43) Pub. Date: May 5, 2022

(54) DISPLAY DEVICE

(71) Applicant: Japan Display Inc., Tokyo (JP)

(72) Inventor: Jun NITTA, Tokyo (JP)

(73) Assignee: Japan Display Inc., Tokyo (JP)

(21) Appl. No.: 17/519,919

(22) Filed: Nov. 5, 2021

(30) Foreign Application Priority Data
Nov. 5, 2020 (JP) 2020-185072

(51) Int. Cl. H01L 27/32

(52) U.S. Cl. CPC H01L 27/3276; H01L 27/3211; H01L 51/5056; H01L 27/3218; H01L 27/3246; H01L 27/3216

(57) ABSTRACT

According to one embodiment, a display device includes a bank covering an edge and a side surface of a pixel electrode and having an opening exposing a part of an upper surface of the pixel electrode, a hole transport layer arranged in the opening and disposed over the pixels, a metal line disposed with the hole transport layer sandwiched on a top area of the bank, a light emitting layer disposed between a plurality of the banks adjacent to each other and disposed in the opening in each of the pixels, wherein the light emitting layer comprises a first light emitting layer in the first pixel, a second light emitting layer in the second pixel, and a third light emitting layer in the third pixel, and the metal line is in contact with the third light emitting layer.

### CROSS-REFERENCE TO RELATED APPLICATIONS

This application is based upon and claims the benefit of priority from Japanese Patent Application No. 2020-185072, filed Nov. 5, 2020, the entire contents of which are incorporated herein by reference.

### FIELD

Embodiments described herein relate generally to a display device.

### BACKGROUND

Display devices using organic electroluminescence (EL) light emitting materials have been developed.

### BRIEF DESCRIPTION OF THE DRAWINGS

FIG. 1A is a plan view of a display device of an embodiment.

FIG. 1B is a plan view of the display device of the embodiment.

FIG. 2 is a cross-sectional view along line A1-A2 of the display device shown in FIG. 1B.

FIG. 3A is a partial enlarged view of a pixel.

FIG. 3B is a partial enlarged view of a pixel.

FIG. 4 is a partial enlarged plan view of the display device.

FIG. 5 is a cross-sectional view showing a configuration example of the display device in the embodiment.

FIG. 6 is a cross-sectional view showing a configuration example of the display device in the embodiment.

FIG. 7 is a cross-sectional view showing a configuration example of the display device in the embodiment.

FIG. 8 is a cross-sectional view showing a configuration example of the display device in the embodiment.

### DETAILED DESCRIPTION

In general, according to one embodiment, a display device comprises a plurality of pixels having a first pixel emitting a first color of light, a second pixel emitting a second color of light, and a third pixel emitting a third color of light, a pixel electrode disposed in each of the pixels, a bank covering an edge and a side surface of the pixel electrode and having an opening exposing a part of an upper surface of the pixel electrode, a hole transport layer arranged in the opening and disposed over the pixels, a metal line disposed with the hole transport layer sandwiched on a top area of the bank, a light emitting layer disposed between a plurality of the banks adjacent to each other and disposed in the opening in each of the pixels, and a counter electrode opposed to the pixel electrode and having the light emitting layer between the pixel electrode and the counter electrode, wherein the light emitting layer comprises a first light emitting layer in the first pixel, a second light emitting layer in the second pixel, and a third light emitting layer in the third pixel, and the metal line is in contact with the third light emitting layer.

According to the present embodiment, a display device capable of suppressing occurrence of a leak current between adjacent pixels can be provided.

Embodiments will be described hereinafter with reference to the accompanying drawings. The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same elements as those described in connection with preceding drawings are denoted by like reference numerals, and a detailed description thereof is omitted unless otherwise necessary.

A display device according to an embodiment will be described hereinafter with reference to the accompanying drawings.

In this embodiment, a first direction X, a second direction Y and a third direction Z are orthogonal to each other, but they may intersect at an angle other than 90 degrees. Further, a direction forwarding a tip of an arrow indicating the third direction Z is defined as “upward” and a direction forwarding oppositely from the tip of the arrow is defined as “downward”.

Further, with such expressions “a second member above a first member” and “a second member below a first member”, the second member may be in contact with the first member or may be remote from the first member. In the latter case, a third member may be interposed between the first member and the second member. On the other hand, with such expressions “a second member on a first member” and “a first member on a second member”, the second member is in contact with the first member.

In addition, it is assumed that there is an observation position to observe the display device on a tip side of an arrow in the third direction Z, and viewing from this observation position toward an X-Y plane defined by the first direction X and the second direction Y is referred to as a planar view. Viewing a cross section of the display device in an X-Z plane defined by the first direction X and the third direction Z or a Y-Z plane defined by the second direction Y and the third direction Z is referred to as a cross-sectional view.

### Embodiment

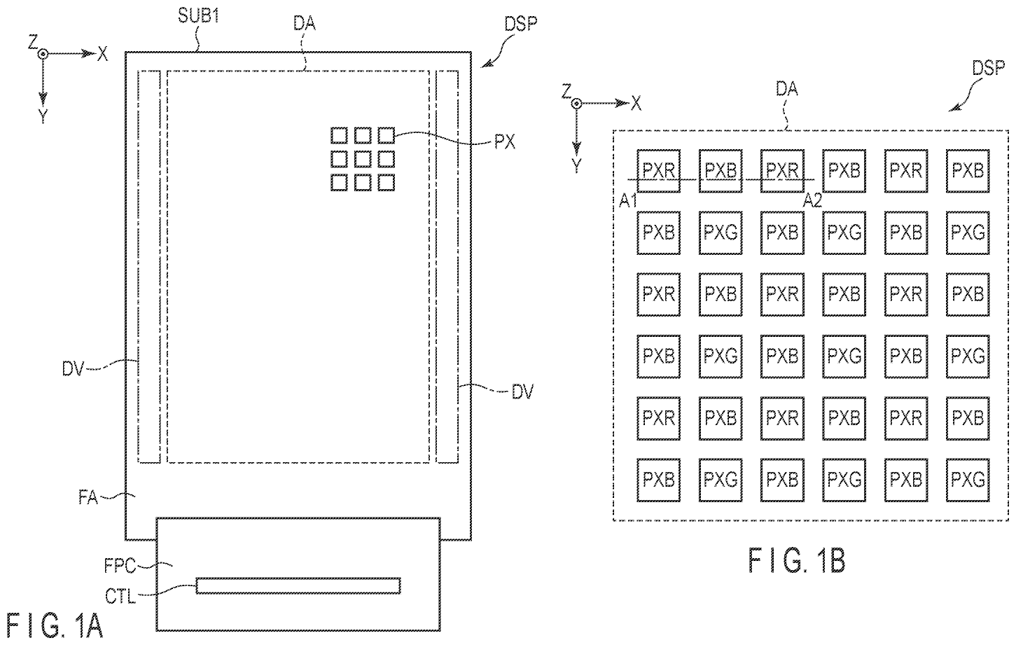

FIG. 1A and FIG. 1B are plan views of a display device of an embodiment. FIG. 1A is an overall plan view of a display device DSP, and FIG. 1B is a partial enlarged view of the display device DSP. In the display device DSP shown in FIG. 1A, a display area DA, a peripheral area FA surrounding the display area DA, and drive circuits DV disposed in the peripheral area FA are disposed in a substrate SUB1.

The display area DA includes a plurality of pixels PX, and the pixels PX are arranged in a matrix.

The peripheral area FA is an area outside the display area DA. The peripheral area FA has the drive circuits DV, and a wiring board FPC connected via a terminal which is not shown in the drawing. A drive element CLT is disposed on the wiring board FPC. The drive element CTL is, for example, a driver IC.

An image signal and various control signals are supplied from the outside of the display device DSP via the wiring board FPC. The image signal is input to the pixels PX via the drive element CTL. Various drive signals are input to the drive circuits DV via the drive element CTL.

The pixels PX each have a light emitting element ELM which will be described later. The light emitting element ELM emits light based on the image signal and the various control signals.

As shown in FIG. 1B, the pixels PX has a pixel PXR which emits the first color of light, a pixel PXG which emits the second color of light, and a pixel PXB which emits the third color of light. The pixels PXR, PXG and PXB are referred to also as the first pixel, the second pixel and the third pixel, respectively. In the present embodiment, the first color, the second color and the third color are red, green and blue, respectively. The pixel PXR is arranged adjacent to the pixel PXB along the first direction X and the second direction Y. The pixel PXG is arranged adjacent to the pixel PXB along the first direction X and the second direction Y. The pixel PXB is arranged adjacent to the pixel PXR along the first direction X, and is arranged adjacent to the pixel PXG along the second direction Y.

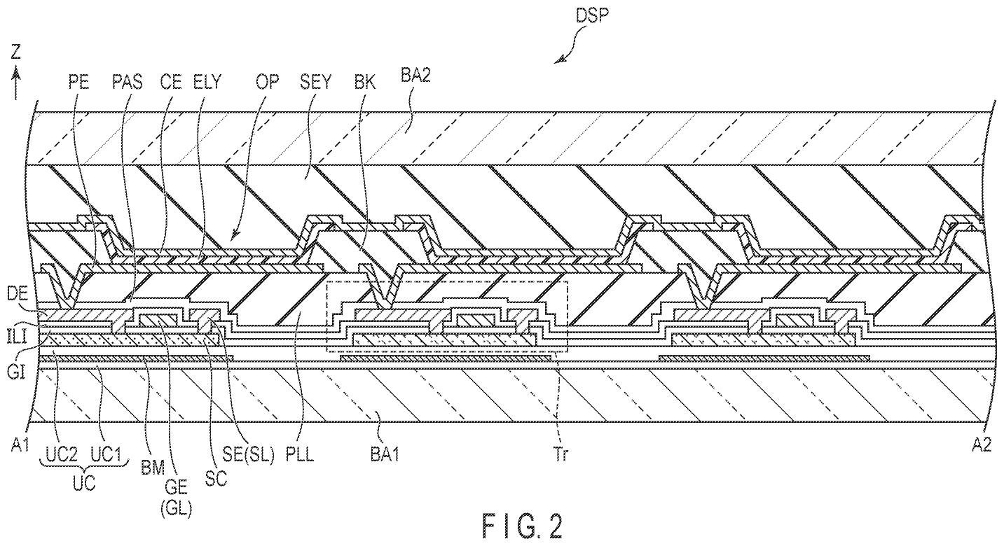

FIG. 2 is a cross-sectional view along line A1-A2 of the display device DSP shown in FIG. 1B.

A base BA1 is a base composed of, for example, glass or a resin material. The resin material may be, for example, acrylic, polyimide, polyethylene terephthalate, polyethylene naphthalate or the like, and may be in the form of a single layer or a stack of layers.

An insulating layer UC1 is disposed on the base BA1. The insulating layer UC1 is formed of, for example, a single layer or a stack of layers of a silicon oxide film and a silicon nitride film.

A light shielding layer BM may be disposed overlapping a transistor Tr on the insulating layer UC1. The light shielding layer BM suppresses a change in transistor characteristics caused by entry of light from the back side of a channel of the transistor Tr or the like. When the light shielding layer BM is formed of a conductive layer, it is possible to impart a back gate effect to the transistor Tr by applying a predetermined potential.

An insulating layer UC2 is disposed covering the insulating layer UC1 and the light shielding layer BM. The same material as the insulating layer UC1 can be used as the material of the insulating layer UC2. It should be noted that the insulating layer UC2 may be formed of a different material from the insulating layer UC1. For example, silicon oxide can be used as the insulating layer UC1, and silicon nitride can be used as the insulating layer UC2. The insulating layers UC1 and UC2 are referred to collectively as an insulating layer UC.

The transistor Tr is disposed on the insulating layer UC. The transistor Tr has a semiconductor SC, an insulating layer GI, a gate electrode GE (scanning line GL), an insulating layer ILI, a source electrode SE (signal line SL) and a drain electrode DE.

As the semiconductor layer SC, amorphous silicon, polysilicon or oxide semiconductor is used.

As the insulating layer GI, for example, silicon oxide or silicon nitride is deposited in a single layer or a plurality of layers.

As the gate electrode GE, for example, molybdenum tungsten alloy (MoW) is used. The gate electrode GE may be integrally formed with the scanning line GL.

An insulating layer ILI is disposed covering the semiconductor layer SC and the gate electrode GE. The insulating layer ILI is formed of, for example, a single layer or a stack of layers of a silicon oxide layer or a silicon nitride layer.

The source electrode SE and the drain electrode DE are disposed on the insulating layer ILI. The source electrode SE and the drain electrode DE are connected to a source area and a drain area of the semiconductor layer SC via contact holes disposed in the insulating layer ILI and the insulating layer GI, respectively. The source electrode SE may be integrally formed with the signal line SL.

An insulating layer PAS is disposed covering the source electrode SE, the drain electrode DE and the insulating layer ILI. An insulating layer PLL is disposed covering the insulating layer PAS.

The insulating layer PAS is formed of an inorganic insulating material. The inorganic insulating material is in the form of, for example, a single layer or a stack of layers of silicon oxide or silicon nitride. The insulating layer PLL is formed of an organic insulating material. The organic insulating material is, for example, an organic material such as photosensitive acrylic or polyimide. By disposing the insulating layer PLL, it is possible to planarize unevenness caused by the transistor Tr.

A pixel electrode PE is disposed on the insulating layer PLL. The pixel electrode PE is connected to the drain electrode DE via a contact hole disposed in the insulating layers PAS and PLL.

The pixel electrode PE is formed of, for example, a three layer stack structure of indium zinc oxide (IZO), silver (Ag) and IZO.

A bank BK (referred to also as a convex portion or a rib) is disposed between the adjacent pixel electrodes PE. The same organic material as the material of the insulating layer PLL is used as the material of the bank BK. The bank BK covers the edge and side surface of the pixel electrode PE. The bank BK is opened to expose a part of the pixel electrode PE. More specifically, an opening OP which exposes a part of the upper surface of the pixel electrode PE is disposed. In addition, the edge of the opening OP should preferably be gently tapered. If the edge of the opening OP is steep, the coverage of an organic EL layer ELY formed later may be impaired.

The organic EL layer ELY is disposed overlapping the pixel electrode PE between the adjacent banks BK. As will be described later in details, the organic EL layer ELY includes a hole transport layer, a light emitting layer and an electron transport layer.

In FIG. 2, in order to make the drawing easy to understand, the organic EL layer ELY is illustrated as being disposed selectively in the pixel PX. However, the organic EL layer ELY is not limited to this. The light emitting layer of the organic EL layer ELY is disposed selectively in the pixel PX. However, the hole transport layer and electron transport layer of the organic EL layer ELY are integrally formed over all the pixels PX. In other words, the hole transport layer and the electron transport layer are disposed solidly. The details will be described later.

A common electrode CE is disposed covering the organic EL layer ELY and the bank BK. As the common electrode CE, a magnesium silver alloy (MgAg) film is formed as such a thin film that light emitted from the organic EL layer ELY can be transmitted. In the present embodiment, the pixel electrode PE is an anode and the common electrode CE is a cathode. The light emitted at the organic EL layer ELY is drawn upward via the common electrode CE. That is, the display device DSP has a top emission structure.

An insulating layer SEY is disposed covering the common electrode CE. The insulating layer SEY has a function of preventing entry of moisture from the outside to the organic EL layer ELY. The insulating layer SEY should preferably have high gas barrier property. The insulating layer SEY is, for example, an insulating layer where an organic insulating layer is sandwiched between two inorganic insulating layers containing nitrogen. The material of the organic insulating layer is acrylic resin, epoxy resin, polyimide resin or the like. The material of the inorganic insulating layers containing nitrogen is, for example, silicon nitride or aluminum nitride.

A base BA2 is disposed on the insulating layer SEY. The base BA2 is formed of the same material as the base BA1. A light transmissive inorganic insulating layer or organic insulating layer may be disposed between the base BA2 and the insulating layer SEY. The organic insulating layer may have a function of bonding the insulating layer SEY and the base BA2 together.

The details of the organic EL layer ELY will be described below. As described above, the hole transport layer of the organic EL layer ELY is disposed over the pixels PX. However, when the hole transport layer is disposed over the pixels PX, a leak current may flow between the adjacent pixels PX.

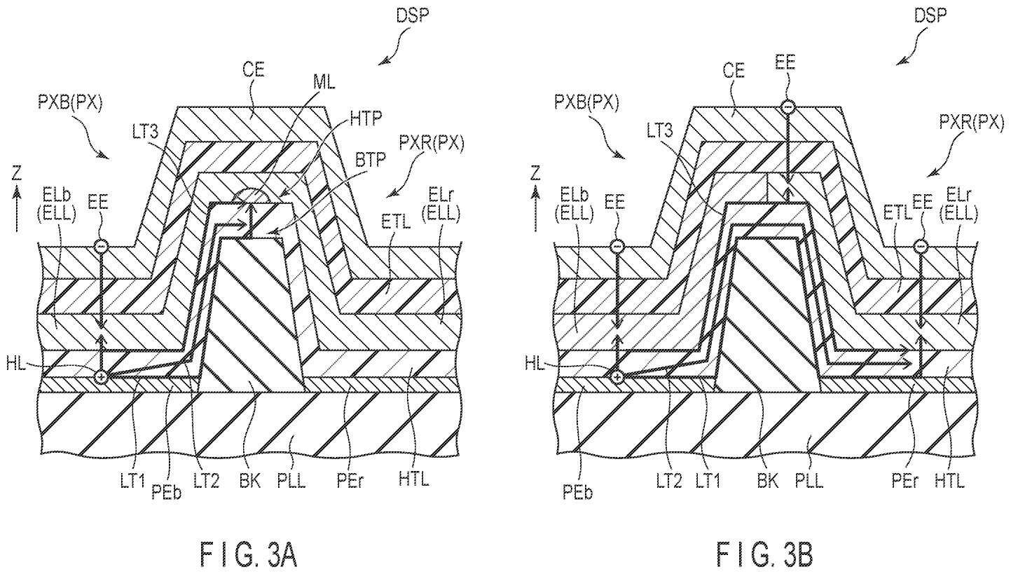

FIG. 3A and FIG. 3B are partial enlarged views of pixels. FIG. 3A is a partial enlarged view of a pixel PX of the embodiment, and FIG. 3B is a partial enlarged view of a pixel PX of a comparative example.

The pixel PX of the present embodiment has the pixel electrode PE, a hole transport layer HTL, a light emitting layer ELL, an electron transport layer ETL and the common electrode CE on the insulating layer PLL. The hole transport layer HTL, the light emitting layer ELL and the electron transport layer ETL are included in the organic EL layer ELY. The light emitting layers ELL included in the pixels PXR, PXG and PXB are referred to as light emitting layers ELr, ELg and ELb, respectively. Also regarding the pixel electrodes PE, pixel electrodes PEr, PEg and PEb are included in the pixels PXR, PXB and PCB, respectively.

The example shown in FIG. 3A shows a boundary area between the pixel PXB which emits blue light and the pixel PXR which emits red light. The pixel PXB has the pixel electrode PEb, the hole transport layer HTL, the light emitting layer ELb emitting blue light, the electron transport layer ETL and the common electrode CE which are stacked in this order on the insulating layer PLL. The pixel PXR has the pixel electrode PEr, the hole transport layer HTL, the light emitting layer ELr emitting red light, the electron transport layer ETL and the common electrode CE which are stacked in this order on the insulating layer PLL. The hole transport layer HTL, the electron transport layer ETL and the common electrode CE are disposed over the pixels PXB and PXR.

As described above, the light emitting elements ELr and ELb each are disposed between the adjacent banks BK. An edge of the light emitting layer ELr and an edge of the light emitting layer ELb are adjacent to each other with the hole transport layer HTL sandwiched on a top area BTP located at the top of the bank BK. In other words, an area HTP located at the top of the hole transport layer HTL is located on the top area BTP of the bank BK, and the edge of the light emitting layer ELr and the edge of the light emitting layer ELb are adjacent to each other on the area HTP.

A metal line ML is disposed in contact with the edge of the light emitting layer ELr and the edge of the light emitting layer ELb and the hole transport layer HTL. The metal line ML is connected to an external fixed power supply which is not shown in the drawing, and is maintained at a predetermined fixed potential. The metal line ML has a function of moving a charge (electron and hole) not contributing to light emission to the outside. The metal line ML may be referred to also as a metal layer.

Here, as a comparative example, a case of not having the metal line ML will be described with reference to FIG. 3B. The example shown in FIG. 3B is the same as FIG. 3A except for not having the metal line ML.

The light emitting layer ELb emitting blue light has a larger energy gap than the light emitting layer ELr emitting red light and the light emitting layer ELg emitting green light. Although a potential is applied to the pixel electrode PEb and the common electrode CE such that only the light emitting layer ELb emits light, the adjacent light emitting layer ELr may emit light due to a leak current. Accordingly, the contrast or color purity of the display device DSP may be reduced.

In the display device DSP, electrons and holes injected from the pixel electrode PE (cathode) and the common electrode CE (cathode) are recombined in the light emitting layer ELL via the electron transport layer ETL and the hole transport layer HTL.

The charge not leading to recombination is built up inside the respective layers of the organic EL layer ELY and causes a charged state, and may cause an energy level change with a structural change by bond cleavage and bond formation of molecules constituting the organic EL layer ELY, intramolecular bond stretching, or the like. Accordingly, the light emission intensity of the organic EL layer ELY decreases inversely with conduction time.

Therefore, in the present embodiment, the metal line ML is disposed in contact with the edge of the light emitting layer ELr and the edge of the light emitting layer ELb and the hole transport layer HLT as shown in FIG. 3A. In particular, the metal layer ML should preferably be arranged in contact with the light emitting layer ELb having a large energy gap.

A hole HL generated in the pixel electrode PEb and an electron EE generated in the common electrode CE are recombined in the light emitting layer ELb and emit light as described above. However, the hole HL may flow to the adjacent light emitting layer ELr via the following three paths LT1 to LT3.

The path LT1 is where the hole HL flows to the adjacent light emitting layer ELr through the interface of the pixel electrode PEb and the hole transport layer HTL and the interface of the bank BK and the hole transport layer HTL. The path LT2 is where the hole HL flows to the adjacent light emitting layer ELr through the inside of the hole transport layer HTL. The path LT3 is where the hole HT flows to the adjacent light emitting layer ELr through the interface of the hole transport layer HTL and the light emitting layer ELL (ELb and ELr).

Although a case where the pixels PXb and PXr (light emitting layers ELb and ELr) are adjacent to each other is described as an example in FIG. 3A, the same applies to a case where the pixels PXb and PXg (light emitting layers ELb and ELg) are adjacent to each other.

When the metal line ML is disposed (see FIG. 3A), the hole HL passing through the path LT1 is attracted to the metal line ML when passing through directly below the metal line ML of the interface of the bank BK and the hole transport layer HTL. The hole HL moves along the thickness direction (third direction Z) of the hole transport layer HTL, is absorbed in the metal line ML, and moves to the outside. Therefore, the hole HL does not reach the light emitting layer ELr.

The hole HL passing through the path LT2 is attracted to the metal line ML containing the electron EE when passing through directly below the metal line ML of the hole transport layer HTL. The hole HL moves along the thickness direction of the hole transport layer HTL, is absorbed in the metal line ML, and flows to the outside. Therefore, the hole HL does not reach the light emitting layer ELr.

The hole HL passing through the path LT3 passes through the interface of the hole transport layer HTL and the light emitting layer ELL, and is absorbed in the metal line ML when passing through the metal line ML disposed in contact with the interface, and flows to the outside. Therefore, the hole HL does not reach the light emitting layer ELr. The hole HL passing through the path LT3 is in contact with the metal line ML. Therefore, the charge (hole HL) is absorbed and moved to the outside more effectively in the path LT3 than in the paths LT1 and LT2.

In the example shown in FIG. 3A, the charge (hole HL) can be moved to the outside via the metal line ML while the charge reaches the adjacent light emitting layer EL, that is, before the leak current contributes to unintended light emission. Accordingly, a decrease in the contrast or color purity of the display device DSP can be suppressed.

A fixed potential (referred to as VM) applied to the metal line ML is lower than a high power supply potential (referred to as VDD) applied to the pixel electrode PE (anode), but is higher than a low power supply voltage (referred to as Vss) applied to the common electrode CE (cathode). That is, VDD>VM>VSS. The voltage VM may be, for example 0 V.

On the other hand, when the metal line ML is not disposed (see FIG. 3B), the hole HL passing through the paths LT1 to LT3 is not absorbed in the metal line ML but reaches the adjacent light emitting layer ELr. Therefore, unintended light emission occurs in the light emitting layer ELr, and color mixture occurs. Consequently, the contrast or color purity of the display device DSP is reduced.

In addition, when the charge moves to the light emitting layer ELL of the adjacent pixel PX, the voltage is increased with the movement of the charge, and the voltage to be applied to the pixel PX is increased accordingly. In order to compensate for the increased voltage, it is necessary to add a voltage corresponding to the increase to drive the pixel PX.

Furthermore, although not shown in the drawing, when the metal line ML is arranged not on the hole transport layer HTL but on the bank BK or in the bank BK, the charge leaking along the interface of the hole transport layer HTL and the bank BK and the interface of the hole transport layer HTL and the pixel electrode PE, that is, the charge passing through the path LT1 can be suppressed.

However, the charge leaking along the interface of the light emitting layer ELL and the hole transport layer HTL, that is, the charge passing through the path LT3 is recombined in the light emitting layer ELL before reaching the metal line ML existing below the hole transport layer HTL. Therefore, unintended light emission occurs on the bank BK or in the adjacent pixel PX.

Therefore, the display device DSP having the metal line ML in contact with the hole transport layer HTL described in the present embodiment prevents color mixture by suppressing unintended light emission, and is suitable for improving the contrast or color purity of the display device DSP. The display device DSP of the present embodiment can suppress an energy level change with a structural change by bond cleavage and bond formation of molecules constituting the organic EL layer ELY, intramolecular bond stretching, or the like. That is, the degradation of the organic EL layer ELY can be prevented. In the display device DSP of the present embodiment, an increase in the drive voltage of the pixel PX can be suppressed by preventing a leak current.

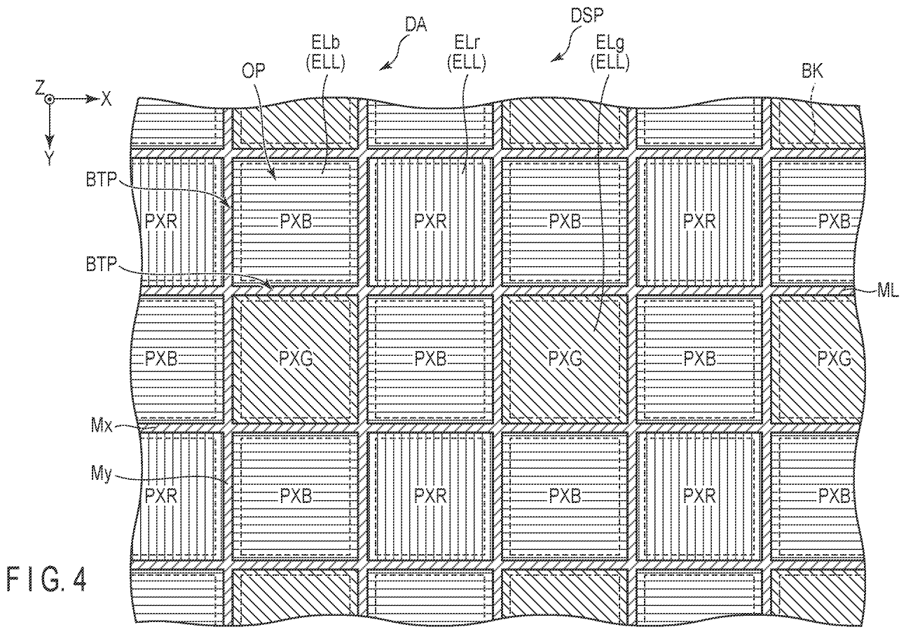

FIG. 4 is a partial enlarged plan view of the display device.

The banks BK are in the form of a lattice extending along the first direction X and the second direction Y. The pixels PX are partitioned according to the shape of the banks BK. Areas surrounded by the lattice-shaped banks BK are openings OP.

The hole transport layer HTL is formed covering the banks BK and the pixel electrodes PE which are not shown in the drawing over the pixels PX.

The light emitting layers ELL (ELr, ELg and ELb) are disposed on the hole transport layer HTL as described above. The edge of each light emitting layer ELL overlaps a part of the bank BK as described above.

The metal lines ML are disposed between the adjacent light emitting layers ELL. The metal lines ML each are disposed on the top area BTP of the bank BK as described above, and are in the form of a lattice as is the case with the banks BK. Part of the metal lines ML which extend along the first direction X are wiring lines Mx, and part of the metal lines ML which extend along the second direction Y are wiring lines My. The wiring lines Mx and My are in contact with each other at intersections thereof. In other words, each pixel PX is surrounded by the wiring lines Mx and My of the metal lines ML.

Since the wiring lines Mx and My are in contact with each other at intersections thereof, the wiring lines Mx and My have the same potential. The wiring lines Mx and My are formed of the same material. When molecules constituting the hole transport layer HTL have orientation and anisotropy in the flow of the hole HL, if the pixel PX is not surrounded by the wiring lines Mx and My or the wiring lines Mx and My are formed of different materials or the wiring lines Mx and My are not in contact with each other at intersections thereof, the effect of suppressing the leaking hole HL may vary. Therefore, the wiring lines Mx and My should preferably be formed of the same material, surround each pixel PX, and be in contact with each other at intersections thereof. The electron transport layer ETL and the common electrode CE are integrally formed over the entire surface.

Each metal line ML only needs to be in contact with at least the light emitting layer ELb having a large energy gap. When the metal line ML is not in contact with the adjacent light emitting layer ELr or ELg, the metal line ML may be in contact with the electron transport layer ETL on the light emitting layer ELr or ELg.

The metal lines ML should preferably be formed by an evaporation method using an evaporation mask. When the metal lines ML are formed by the evaporation method, damage to the organic EL layer ELY can be suppressed. However, the method for forming the metal lines ML is not limited to this but may be another method.

In the display device DSP of the present embodiment, each metal line ML is formed with the hole transport layer HTL sandwiched on the top area BTP of the convex bank BK delimiting the pixel PX. The metal line ML can pass the leak current generated by the movement of the charge (hole HL) to the outside before the leak current contributes to light emission. Accordingly, the decrease in the contrast or color purity can be suppressed. In addition, in the display device of the present embodiment, the degradation of the organic EL layer ELY can be prevented. In the display device DSP of the present embodiment, the increase in the drive voltage of the pixel PX can be suppressed by preventing the leak current.

### Configuration Example 1

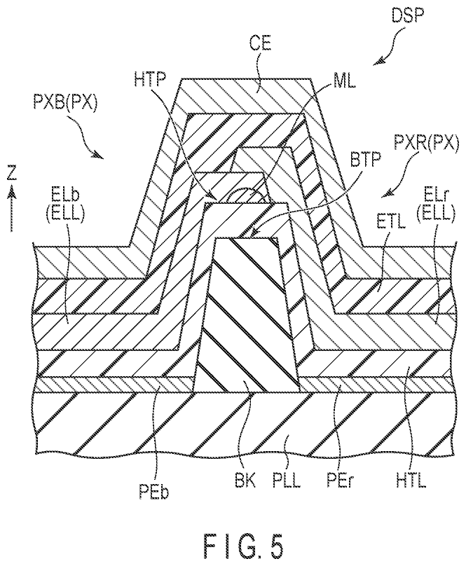

FIG. 5 is a cross-sectional view showing another configuration example of the display device in the embodiment. The configuration example shown in FIG. 5 is different from the configuration example shown in FIG. 3A in that the light emitting layer emitting blue light covers the metal line.

In the display device DSP shown in FIG. 5, the metal line ML is arranged with the area HTP of the hole transport layer HTL sandwiched on the top area BTP of the bank BK. The light emitting layer ELb emitting blue light is disposed covering the metal line ML.

The light emitting layer ELr emitting red light is in contact with the hole transport layer HTL and the light emitting layer ELb but is not in contact with the metal line ML. Also when the light emitting layer ELg emitting green light is formed, as is the case with the light emitting layer ELr, the light emitting layer ELg is not in contact with the metal line ML.

The light emitting layer ELb emits light at a higher potential than the light emitting layer ELr. In the pixel PXB, holes not contributing to light emission are generated even at low voltage. When the light emitting layer ELb is in contact with the metal line ML, the hole HL not contributing to light emission is drawn to the outside via the metal line ML, and unintended light emission does not occur. Since the charge (hole HL) is drawn to the outside, the organic EL layer ELY including the light emitting layer ELL is not degraded.

Therefore, as long as the light emitting layer ELb is in contact with the metal line ML, the light emitting layers ELr and ELg do not need to be in contact with the metal line ML.

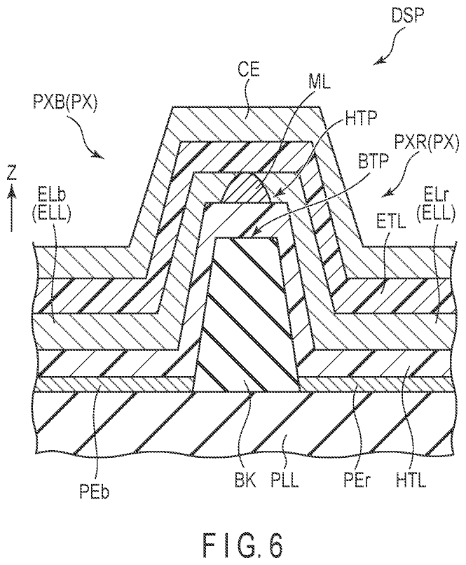

FIG. 6 is a cross-sectional view showing another configuration example of the display device in the embodiment. The configuration example shown in FIG. 6 is different from the configuration example shown in FIG. 3A in that the thickness of the metal line ML is the same as the light emitting layer ELL.

The metal line ML is in contact with the light emitting layers ELb and ELr. The light emitting layers ELb and ELr are not in contact with each other due to the metal line ML held therebetween. Also when the light emitting layer ELg emitting green light is formed, as is the case with the light emitting layer ELr, the light emitting layer ELg is not in contact with the light emitting layer ELb.

The same effects as the embodiment can also be produced in the present configuration example.

### Configuration Example 2

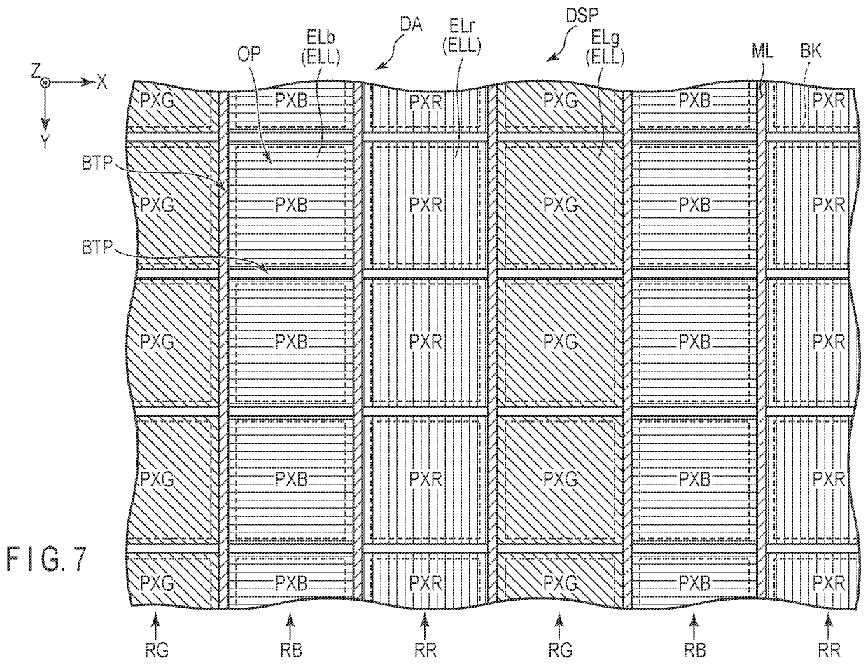

FIG. 7 is a cross-sectional view showing another configuration example of the display device in the embodiment. The configuration example shown in FIG. 7 is different from the configuration example shown in FIG. 4 in that the pixels are arranged in a stripe layout.

In the display device DSP shown in FIG. 7, the pixels of the same color are arranged in the same column. For example, the pixels PXB are arranged along the second direction Y and form a pixel column PB. The pixels PXR are arranged along the second direction Y and form a pixel column RR. The pixels PXG are arranged along the second direction Y and form a pixel column RG. The pixel column RR is arranged between the pixel columns RB and RG. The pixel column RG is arranged between the pixel columns RG and RB. The pixel column RB is arranged between the pixel columns RG and RR.

In other words, the pixel columns RR, RG and RB extend along the second direction Y, and are arranged along the first direction X. The pixel columns RR, RG and RB may be referred to also as the first pixel column, the second pixel column and the third pixel column.

The metal lines ML extend along the second direction Y and are arranged along the first direction X on the banks BK. The metal lines ML are disposed between the pixel columns of different colors. That is, the metal lines ML are disposed between the pixel column RR (first pixel column) and the pixel column RG (second pixel column), between the pixel column RG (second pixel column) and the pixel column RB (third pixel column), and between the pixel column RB (third pixel column) and the pixel column RR (first pixel column), respectively.

In the example shown in FIG. 7, the pixels PX of the same color are arranged in one pixel column. It is not necessary to dispose the metal lines ML between the pixels PX of the same color in one pixel column. That is, unlike the example shown in FIG. 4, the metal lines (wiring lines Mx of FIG. 4) extending along the first direction X may not be disposed.

However, as is the case in FIG. 5, each metal line ML only needs to be in contact with at least the light emitting layer ELb. When the light emitting layer ELb covers the metal line ML, the light emitting layers ELr and ELg may not be in contact with the metal line ML. In addition, the metal line ML may not be disposed between the pixel PXR and the pixel PXG. When the metal line ML is disposed between the pixel PXR and the pixel PXG, the metal line ML between the pixel PXR and the pixel PXG only needs to be in contact with at least the light emitting layer ELg. When the metal line ML is disposed between the pixel PXR and the pixel PXG, if the light emitting layer ELg covers the metal line ML between the pixel PXr and the pixel PXG, the light emitting layer ELr may not be in contact with the metal line ML between the pixel PXR and the pixel PXG.

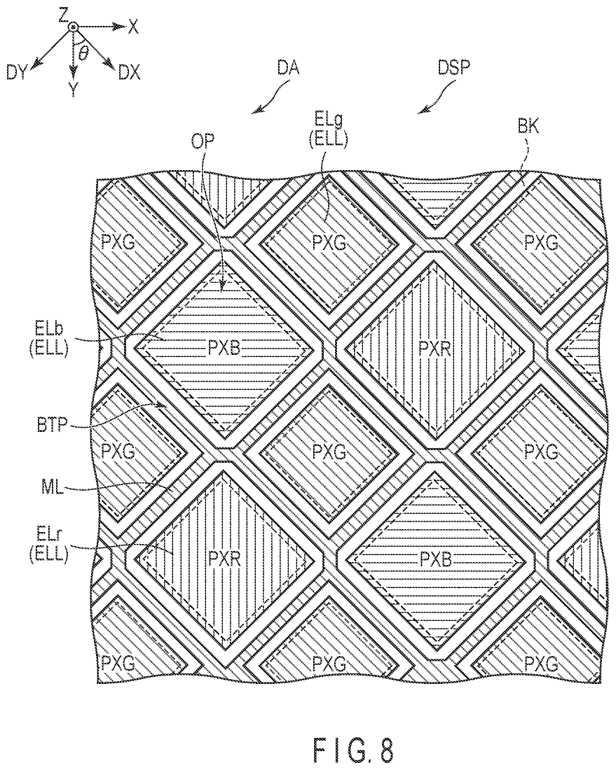

FIG. 8 is a cross-sectional view showing another configuration example of the display device in the embodiment. The configuration example shown in FIG. 8 is different from the configuration example shown in FIG. 7 in that the pixels are arranged in a pentile layout.

In FIG. 8, a direction intersecting at an acute angle θ counterclockwise with respect to the second direction Y is defined as a direction DX, and a direction perpendicular to the direction DX is defined as a direction DY. The acute angle 9 is, for example, 45 degrees. The pentile layout illustrated in FIG. 8 is referred to also as a diamond pentile layout.

In the display device DSP shown in FIG. 8, each pixel PX has the diamond-shaped opening OP. However, the opening OP of the pixel PXG is smaller than the openings OP of the pixels PXR and PXB.

The pixels PXB are arranged along the first direction X and the second direction Y. The pixels PXG include those which each are adjacent to the pixel PXR along the direction DX and those which each are adjacent to the pixel PXB along the direction DX. Each pixel PXG adjacent to the pixel PXR along the direction DX is adjacent to the pixel PXB along the direction DY. Each pixel PXG adjacent to the pixel PXB along the direction DX is adjacent to the pixel PXR along the direction DY.

Each pixel PXR is arranged adjacent to the pixel PXB along the first direction X and the second direction Y. Each pixel PXR is arranged adjacent to the pixel PXG along the directions DX and DY.

Each pixel PXB is arranged adjacent to the pixel PXR along the first direction X and the second direction Y. Each pixel PXB is arranged adjacent to the pixel PXG along the directions DX and DY.

The banks BK are substantially in the form of a lattice along the schematic directions DX and DY. The pixels PX are partitioned according to the shape of the banks BK. Areas surrounded by the lattice-shaped banks BK are the openings OP.

On the top area BTP located at the top of each bank BK, the metal line ML is disposed with the hole transport layer HTL sandwiched, which is not shown in the drawing. As is the case with the banks BK, the metal lines ML extend along the schematic directions DX and DY and are substantially in the form of a lattice.

The metal lines ML are disposed between the light emitting layers ELb and ELg and between the light emitting layers ELr and ELg. The metal lines ML are in contact with the light emitting layers ELr, ELg and ELb.

However, as is the case in FIG. 5, each metal line ML only needs to be in contact with at least the light emitting layer ELb. When the light emitting layer ELb covers the metal line ML, the light emitting layers ELr and ELg may not be in contact with the metal line ML.

The same effects as the present embodiment can also be produced in the present configuration example.

While certain embodiments have been described, these embodiments have been presented by way of example only, and are not intended to limit the scope of the inventions. Indeed, the novel embodiments described herein may be embodied in a variety of other forms, furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a plurality of pixels having a first pixel emitting a first color of light, a second pixel emitting a second color of light, and a third pixel emitting a third color of light;
a pixel electrode disposed in each of the pixels;
a bank covering an edge and a side surface of the pixel electrode and having an opening exposing a part of an upper surface of the pixel electrode;
a hole transport layer arranged in the opening and disposed over the pixels;
a metal line disposed with the hole transport layer sandwiched on a top area of the bank;
a light emitting layer disposed between a plurality of the banks adjacent to each other and disposed in the opening in each of the pixels; and
a counter electrode opposed to the pixel electrode and having the light emitting layer between the pixel electrode and the counter electrode, wherein
the light emitting layer comprises a first light emitting layer in the first pixel, a second light emitting layer in the second pixel, and a third light emitting layer in the third pixel, and
the metal line is in contact with the third light emitting layer.

2. The display device according to claim 1, wherein the metal line is in contact with the first light emitting layer and the second light emitting layer.

3. The display device according to claim 1, wherein
the first color is red, the second color is green, and the third color is blue,
the metal line is covered with the third light emitting layer but is not in contact with the first light emitting layer and the second light emitting layer.

4. The display device according to claim 1, wherein a thickness of the metal line is a same as a thickness of the light emitting layer.

5. The display device according to claim 1, wherein
a plurality of the first pixels, a plurality of the second pixels and a plurality of the third pixels form a first pixel column, a second pixel column and a third pixel column arranged along a first direction, and extending along a second direction intersecting the first direction, respectively, and
a plurality of the metal lines are disposed between the first pixel column and the second pixel column, between the second pixel column and the third pixel column, and between the third pixel column and the first pixel column.

6. The display device according to claim 5, wherein the metal lines are not disposed along the first direction.

7. The display device according to claim 1, wherein
the first pixel, the second pixel and the third pixel are arranged in a pentile layout, and
a plurality of the metal lines are disposed between the first light emitting layer and the second light emitting layer, between the second light emitting layer and the third light emitting layer, and between the third light emitting layer and the first light emitting layer, respectively.
